(19) United States
(12) Patent Application Publication
(10) Pub. No.: US 2007/0228492 A1
(43) Pub. Date: Oct. 4, 2007

(54) SUBSTRATE STRIP AND COMPACT CAMERA MODULE UTILIZING THE SAME

(75) Inventors: She-Hong CHENG, Tainan City (TW); Ya-Lan Huang, Kaohsiung City (TW); Kuo-Hua Chen, Magong City (TW); Shiuan-Ming Su, Nantou County (TW)

Correspondence Address: LOWE HAUPTMAN BERNER, LLP, 1700 DIAGONAL ROAD, SUITE 300, ALEXANDRIA, VA, 22314, US

(73) Assignee: ADVANCED SEMICONDUCTOR ENGINEERING INC., KAOHSIUNG (TW)

(21) Appl. No.: 11/556,491

(22) Filed: Nov. 3, 2006

(30) Foreign Application Priority Data
Apr. 4, 2006 (TW) 095112017

(51) Int. Cl. H01L 29/76

(52) U.S. Cl. 257/401

(57) ABSTRACT

A substrate strip includes a plurality of substrate units. A plurality of fingers is disposed in the substrate units. At least one of the corners of the fingers has a lead angle. A plurality of milling slots is formed on the peripheries of the substrate units and exposes out of the exposed sides of the fingers. The lead angles are adjacent to the exposed sides and can reduce the formation of burrs on the fingers during the formation of the milling slots. In another embodiment, a plurality of pads is provided if the fingers fail to be adjacent to the milling slots. Likewise, at least one of the corners of the pads also has a lead angle so as to reduce the formation of burrs on the pads during formation of the milling slots.

### CROSS REFERENCE TO RELATED APPLICATION

This application claims the priority benefit of Taiwan Patent Application Serial Number 095112017 filed Apr. 4, 2006, the full disclosure of which is incorporated herein by reference.

### BACKGROUND OF THE INVENTION

1. Field of the Invention

The present invention relates to a punch type substrate strip and a compact camera module utilizing the same, and more particularly, to a substrate strip with fewer burrs formed during the formation of the substrate strip and a compact camera module utilizing the substrate strip.

2. Description of the Related Art

A punch type substrate strip includes a plurality of substrate units integrally formed with each other. The substrate units are adapted to carry chips or devices so as to form electronic modules, such as compact camera module (CCM). Conventionally, milling slots are formed on the edge of each substrate unit by a milling cutter before the module process so as to facilitate the separation of the substrate units from each other by punch press operation after the substrate units have been assembled into electronic modules. However, metal burrs are apt to be formed on the substrate units during the formation of the milling slots. This is because the metal components of the substrate strip, such as plating bars or fingers are milled by the milling cutter. If the plating bars are milled, an open circuit problem will occur. If the milling cutter frequently mills the fingers or the metal components of larger area, the milling cutter will easily wear out.

Accordingly, there exists a need to provide a substrate strip to solve the aforesaid problems.

### SUMMARY OF THE INVENTION

It is an object of the present invention to provide a substrate strip and the compact camera module utilizing the same. The substrate strip includes a plurality of substrate units. The substrate unit includes a plurality of fingers or pads. At least one of the corners of the fingers or pads has a lead angle. A plurality of milling slots are formed on the edges of the substrate units. One of the sides of the finger or pad adjacent to the lead angle is exposed out of the milling slot. The lead angle on the exposed side can reduce the formation of metal burrs on the finger during the formation of the milling slots. Accordingly, the production cost of the substrate strip can be reduced.

It is another object of the present invention to provide a substrate strip and the compact camera module utilizing the same. The length of the exposed side is smaller than the width of the finger and greater than the widths of the traces deployed on the substrate units so as to decrease the milling length of the finger and prevent the traces from being torn or pulled off.

According to the present invention, a substrate strip includes a plurality of substrate units. The substrate unit includes a plurality of fingers or pads. At least one of the corners of the fingers or pads has a lead angle. A plurality of milling slots are formed on the edges of the substrate units. One of the sides of the finger or pad adjacent to the lead angle is exposed out of the milling slot. The lead angle on the exposed side can reduce the formation of metal burrs on the finger during the formation of the milling slots.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of a substrate strip according to the present invention.

FIG. 2 is an enlarged view of a substrate unit of FIG. 1 according to the first embodiment of the present invention.

FIG. 3 is an enlarged view of a portion of the substrate of FIG. 2.

FIG. 4 is a cross-sectional view of a compact camera module utilizing the substrate unit of FIG. 2 according to the present invention.

FIG. 5 is an enlarged view of a substrate unit of FIG. 1 according to the second embodiment of the present invention.

FIG. 6 is an enlarged view of a portion of the substrate of FIG. 5.

### DETAILED DESCRIPTION OF THE PREFERRED EMBODIMENT

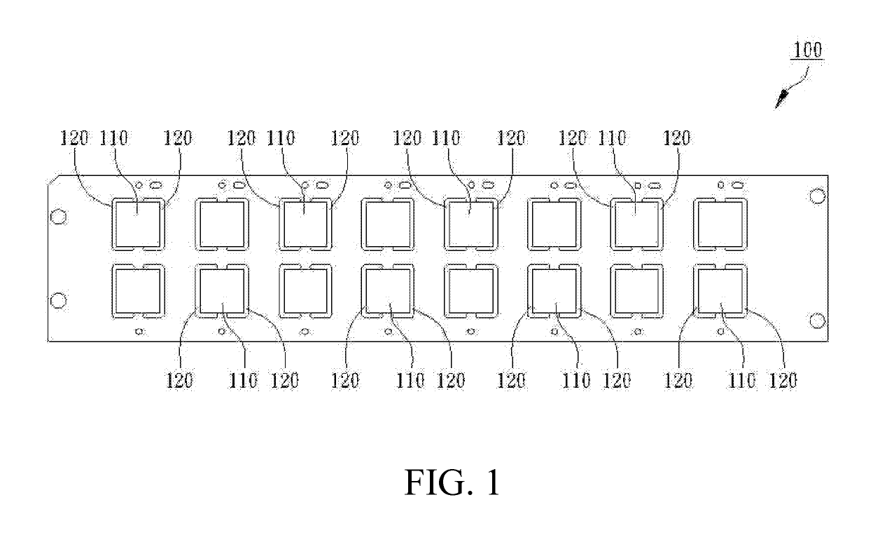

The present invention will be illustrated in the following embodiments. Referring to FIGS. 1, 2 and 3, a substrate strip 100 according to the first embodiment of the present invention includes a plurality of substrate units 110 and a plurality of milling slots 120 formed on the edges of the substrate units 110. The substrate unit 110 includes a plurality of metal layers 111, such as fingers disposed thereon. At least one lead angle 114 is formed on at least one of the corners of the metal layers 111. In this embodiment, two u-shaped milling slots 120 are formed on the edge of the substrate unit 110. The u-shaped milling slots 120 can facilitate the separation of the substrate units 110 from each other by punch press operation. A side 113 of the metal layer 111 adjacent to the lead angle 114 is exposed out of the milling slot 120. The lead angle 114 on the exposed side 113 can reduce the formation of metal burrs on the metal layer 111 during the formation of the milling slots 120. In different embodiments, both of the two corners of the metal layers 111 adjacent to the exposed side 113 have the lead angles 114.

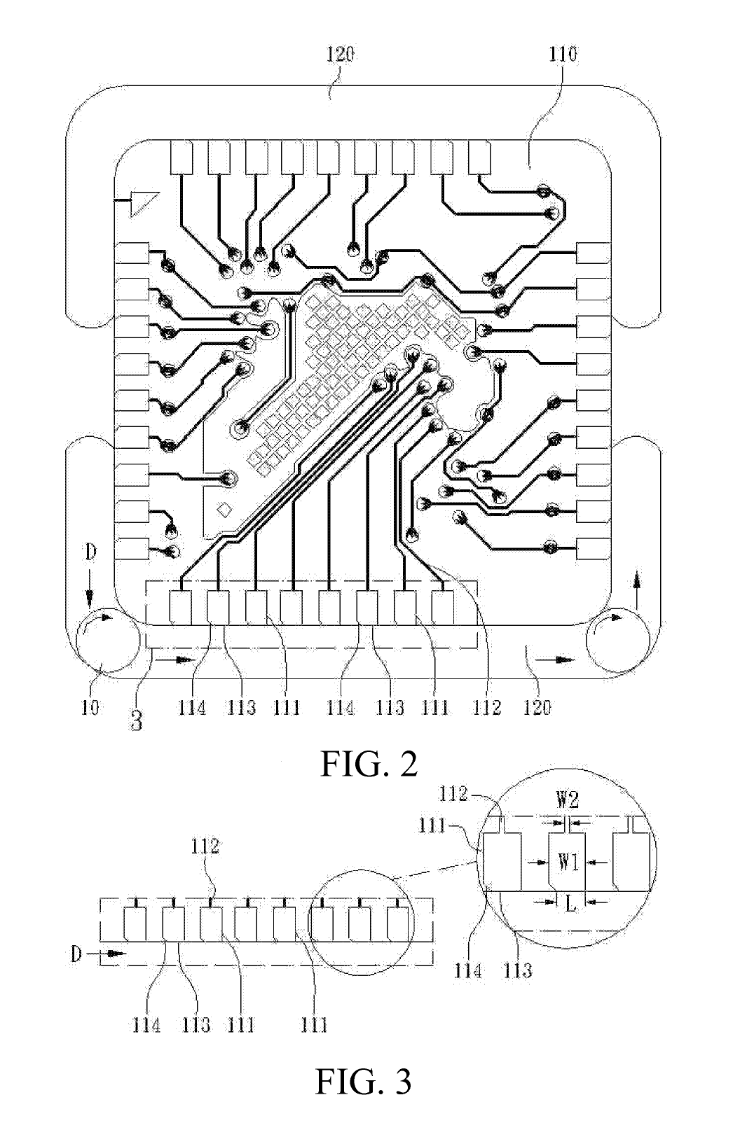

Referring again to FIGS. 2 and 3, the lead angles 114 of the metal layers 111 located in the same side of the substrate unit 110 face the same direction, preferably, opposite to the milling direction D. Since the direction the milling cutter 10 spins is opposite to the milling direction D during the formation of the milling slots 120, the corner with the lead angle 114 will first be milled when the milling cutter 10 meets the metal layer 111. The lead angles 114 of the metal layers 111 can provide extra space for milling, and thus shorten the milling cycle time. The lead angles 114 can also reduce the formation of metal burrs on the metal layers 111 during the formation of the milling slots 120 and the wear out of the milling cutter 10. Accordingly, the production cost of the substrate strip 100 can be reduced.

Referring again to FIG. 3, preferably, the length L of the exposed side 113 is smaller than the width W1 of the metal layer 111 and greater than the widths W2 of the traces 112 deployed on the substrate units 110 so as to decrease the milling length of the metal layer 111 and prevent the traces 112 from being torn or pulled off.

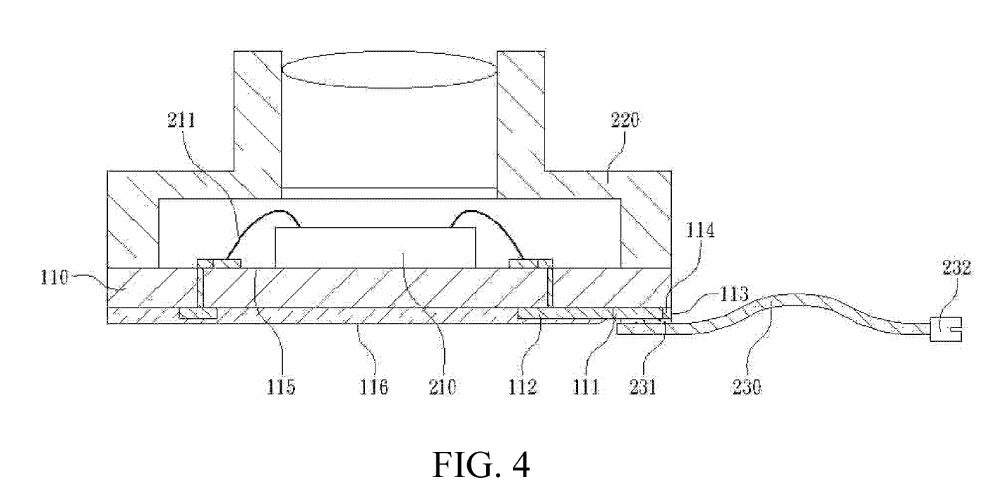

Referring to FIG. 4, a substrate unit 110 has a device surface 115 and an outer connecting surface 116. The metal layers 111 are exposed out of the outer connecting surface 116. As a compact camera module is provided with the substrate unit 110, a sensor chip 210 is disposed on the device surface 115 and a lens module 220 comprised of an optical lens and a filter covers and airtightly seals the sensor chip 210. The lens module 220 can also focus rays of light to the sensor chip 210. As the metal layers 111 are disposed on the outer connecting surface 116 and do not occupy the device surface 115 and also the lead angles 114 of the metal layers 111 can reduce the formation of metal burrs on the metal layers 111, the profile of the substrate unit 110 can be reduced. In this embodiment, the compact camera module further includes a soft circuit board 230. One end of the soft circuit board 230 is connected to the metal layers 111 by anisotropic conductive adhesive 231 and the other end is provided with a connector 232 to connect with an appliance.

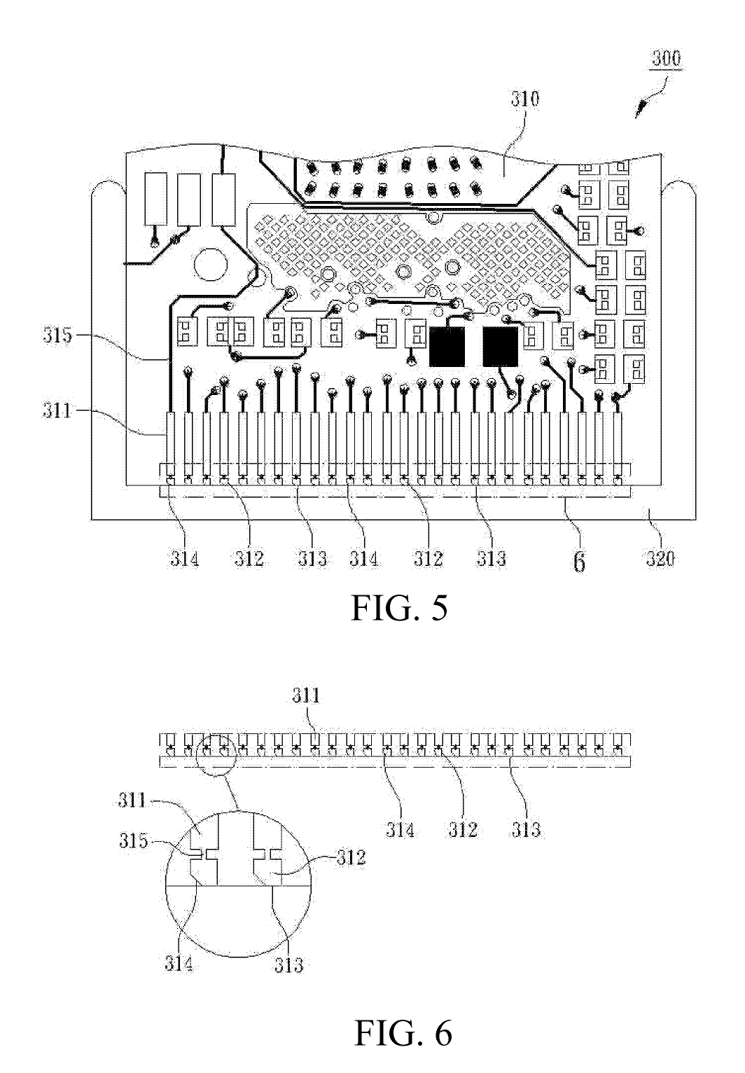

Referring to FIGS. 5 and 6, a substrate strip 300 according to the second embodiment of the present invention includes a plurality of substrate units 310. A plurality of metal layers 311, such as fingers and a plurality of metal layers 312, such as pads, are disposed on the substrate unit 310. At least one of the corners of the metal layers 312 has a lead angle 314. A plurality of milling slots 320 are formed on the edges of the substrate units 310. A side 313 of the metal layer 312 adjacent to the lead angle 314 is exposed out of the milling slot 320. The lead angle 314 on the exposed side 313 can reduce the formation of metal burrs on the metal layer 311 during the formation of the milling slot 320. In this embodiment, a plurality of conductive traces 315 electrically connects the metal layers 311 and metal layers 312. The conductive traces 315 can be further deployed such that the conductive traces 315 pass through via holes of the substrate unit 310.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A substrate strip, comprising:
a plurality of substrate units;
a plurality of first metal layers disposed on the substrate units;
at least one lead angle formed on at least one of the corners of the first metal layers; and
a plurality of milling slots formed on the edges of the substrate units,
wherein one of the sides of the first metal layer adjacent to the lead angle is exposed out of the milling slot.

2. The substrate strip as claimed in claim 1, wherein each of the substrate units has an outer connecting surface, and the first metal layers are exposed out of the outer connecting surfaces.

3. The substrate strip as claimed in claim 1, wherein the lead angles of the first metal layers located in the same side of the substrate unit face the same direction.

4. The substrate strip as claimed in claim 1, wherein the milling slots are u-shaped.

5. The substrate strip as claimed in claim 1, wherein the length of the exposed side of the first metal layer is smaller than the width of the first metal layer and greater than the widths of a plurality of traces deployed on the substrate units.

6. The substrate strip as claimed in claim 1, further comprising:
a plurality of second metal layers disposed on the substrate units, electrically connecting with the first metal layers.

7. The substrate strip as claimed in claim 6, wherein each of the substrate units has an outer connecting surface, and the first metal layers are exposed out of the outer connecting surfaces.

8. The substrate strip as claimed in claim 7, wherein the second metal layers are exposed out of the outer connecting surfaces.

9. The substrate strip as claimed in claim 6, wherein the lead angles of the first metal layers located in the same side of the substrate unit face the same direction.

10. The substrate strip as claimed in claim 6, wherein the milling slots are u-shaped.

11. The substrate strip as claimed in claim 6, wherein the length of the exposed side of the first metal layer is smaller than the width of the first metal layer and greater than the widths of a plurality of traces deployed on the substrate units.

12. A compact camera module, comprising:
a substrate unit;
a plurality of first metal layers disposed on the substrate unit, wherein one side of the first metal layer is exposed out of the edge of the substrate unit;
at least one lead angle formed on at least one of the corners of the first metal layers and disposed on the exposed sides of the first metal layers; and
a sensor chip disposed on the substrate unit.

13. The compact camera module as claimed in claim 12, wherein the substrate unit has a device surface and an outer connecting surface, the sensor chip is disposed on the device surface, the first metal layers are exposed out of the outer connecting surface.

14. The compact camera module as claimed in claim 12, further comprising:
a soft circuit board connected to the first metal layers.

15. The compact camera module as claimed in claim 12, wherein the lead angles of the first metal layers located in the same side of the substrate unit face the same direction.

16. The compact camera module as claimed in claim 12, wherein the length of the exposed side of the first metal layer is smaller than the width of the first metal layer and greater than the widths of a plurality of traces deployed on the substrate units.

17. The compact camera module as claimed in claim 12, further comprising:
a plurality of second metal layers disposed on the substrate unit, electrically connecting with the first metal layers.
